(19) United States
(12) Patent Application Publication
(10) Pub. No.: US 2010/0259282 A1
(43) Pub. Date: Oct. 14, 2010

(54) DETECTOR FOR PROXIMITY SENSOR AND PROXIMITY SENSOR

(75) Inventors: Masahisa Niwa, Osaka (JP); Sukoya Tawaratsumida, Hyogo (JP)

Correspondence Address: GREENBLUM & BERNSTEIN, P.L.C., 1950 ROLAND CLARKE PLACE, RESTON, VA, 20191, US

(73) Assignee: PANASONIC ELECTRIC WORKS CO., LTD., Osaka (JP)

(21) Appl. No.: 12/678,493

(22) PCT Filed: Sep. 3, 2008
(86) PCT No.: PCT/JP2008/065812

§ 371 Date: Mar. 17, 2010

(30) Foreign Application Priority Data
Sep. 20, 2007 (JP) 2007-244341
Dec. 25, 2007 (JP) 2007-332208

(51) Int. Cl. G01R 27/28

(52) U.S. Cl. 324/655

(57) ABSTRACT

A detector for a proximity sensor, includes: a sensing portion including a pair of sensing coils which has central axes along a direction intersecting with a moving direction of a sensed object moving in a predetermined moving path and is provided so as to interpose the moving path; a circuit block including a capacitor composing an LC resonant circuit with the sensing coils of the sensing portion and provided with an oscillator which oscillates the LC resonant circuit; and an electric connector composed of first connection terminals and a first conductor pattern that connect the sensing coils of the sensing portion in series, and second connection terminals and a second conductor pattern that connect the sensing coils to the oscillator.

### TECHNICAL FIELD

The present invention relates to a detector for a high-frequency oscillation type proximity sensor and a proximity sensor using the same.

### BACKGROUND ART

Conventionally, as a non-contact proximity sensor for sensing a sensed object made of metals (conductive materials), magnetic materials, and the like, a high-frequency oscillation type proximity sensor has been suggested. The high-frequency oscillation type proximity sensor includes an LC resonant circuit composed of a parallel circuit of a sensing coil and a capacitor. The proximity sensor senses a sensed object by use of a phenomenon that an eddy current loss is occurred due to an electromagnetic induction effect so as to change in conductance (impedance) of the sensing coil, when the sensed object is close to the sensing coil composing the LC resonant circuit. In other words, when the conductance of the sensing coil is changed, an oscillation condition of the LC resonant circuit is also changed. Thus, the proximity sensor determines a presence of the sensed object when a state where the LC resonant circuit is oscillated is shifted to a state where an oscillation of the LC resonant circuit is stopped or more than a predetermined value of oscillation amplitude is reduced. Such a type of the proximity sensor in which a plurality of coils are used in order to improve a sensing sensitivity of the sensed object has been suggested in Patent Literature PTL 1. It is described in Patent Literature PTL 1 that an inductance of coils is largely varied by providing the plurality of (a pair of) the coils connected in series and configured to face each other interposing a detection path.

When the plurality of the coils connected in series were used as described in the Patent Literature PTL 1, a part of the same winding (conductor wire) was provided with a plurality of parts as coils. As a result, when a relatively expensive material was used for the conductor wire in order to improve a sensing sensitivity, a problem to increase a production cost was occurred. Such a problem was similarly occurred when a plurality of coils connected in parallel were used. In addition, in the conventional proximity sensor, the conductance of the sensing coils is largely varied due to an ambient temperature, and sensor characteristics varies according to the ambient temperature since the sensing coils are made of a material having a large temperature coefficient of resistance such as copper.

The present invention has been made in consideration for the above-mentioned problem. It is an object of the present invention to provide a detector for a proximity sensor achieving low cost while improving a sensing sensitivity, and having sensor characteristics with small temperature dependency, and provide a proximity sensor using the detector.

### CITATION LIST

### Patent Literature

[PTL 1] Japanese Patent Application Laid-Open Publication No. S60-235524 (published in 1985)

### SUMMARY OF INVENTION

According to a detector for a proximity sensor according to the present invention including: one or more of sensing portions, each of the sensing portions including at least one pair of sensing coils which has central axes along a direction intersecting with a moving direction of a sensed object moving in a predetermined moving path and is provided so as to interpose the moving path; a circuit block including a capacitor composing an LC resonant circuit with the sensing coils of the sensing portion and provided with an oscillator which oscillates the LC resonant circuit; and an electric connector composed of conductive materials, connecting the sensing coils of the sensing portion in series or in parallel, and connecting the sensing coils to the oscillator.

### BRIEF DESCRIPTION OF DRAWINGS

FIG. 1 is an exploded perspective view omitting some parts of a detector for a proximity sensor in a first embodiment of the present invention.

FIGS. 2(a) and 2(b) are views illustrating an example of use of the detector for a proximity sensor illustrated in FIG. 1.

FIG. 3 is a circuit block diagram of a proximity sensor using the detector for a proximity sensor illustrated in FIG. 1.

FIGS. 4(a) to 4(c) are experimental results evaluating temperature dependency of a conductance with regard to copper, copper-nickel alloy and copper-manganese alloy, respectively.

FIG. 5 is a perspective view omitting some parts of a detector for a proximity sensor in a second embodiment of the preset invention.

FIG. 6 is a perspective view omitting some parts of a detector for a proximity sensor in a third embodiment of the preset invention.

FIG. 7 is an exploded perspective view omitting some parts of the detector for a proximity sensor illustrated in FIG. 6.

### DESCRIPTION OF EMBODIMENTS

### First Embodiment

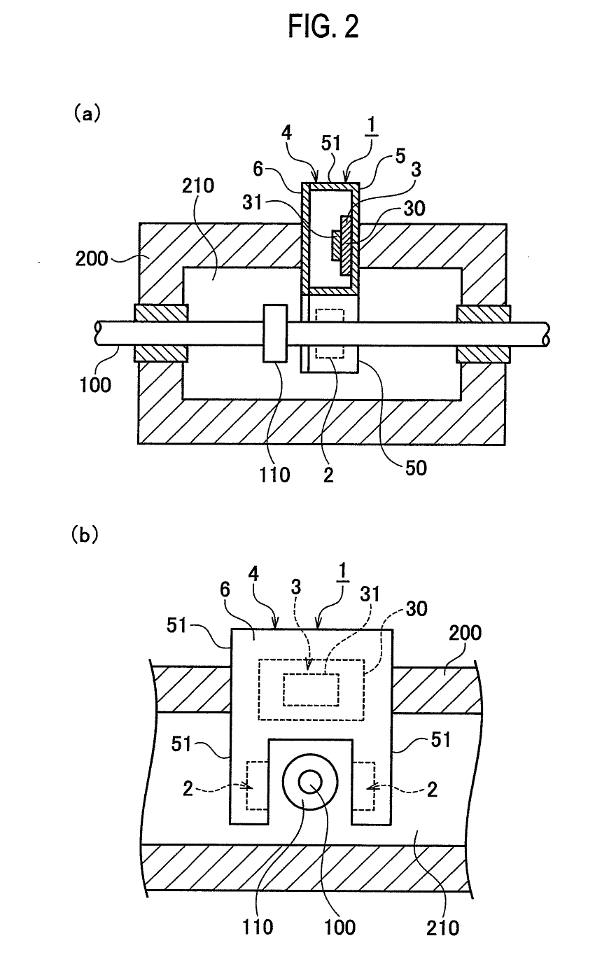

A proximity sensor in a first embodiment of the present invention is used, for example, for detecting whether a linear solenoid valve used for a hydraulic controller of an automatic transmission of a vehicle and the like operates normally or not. As illustrated in FIGS. 2(a) and 2(b), for example, the hydraulic controller includes a device main body 200 provided with a flow path 210 of driving oil (not illustrated), and is provided with a movable body 100 in the flow path 210 of the device main body 200. The movable body 100 is provided with a sensed object 110 concurrently moved with the movable body 100. The sensed object 110 has a disk-like shape having a radius larger than a radius of the movable body 100 (i.e. a cross section in the surface configured to have a different shape from a cross section of the movable body 100), and a central axis thereof is configured to have a corresponding shape to a central axis of the movable body 100. Note that, both of the movable body 100 and the sensed object 110 are configured to have a circle in a cross-section surface perpendicular to the central axis.

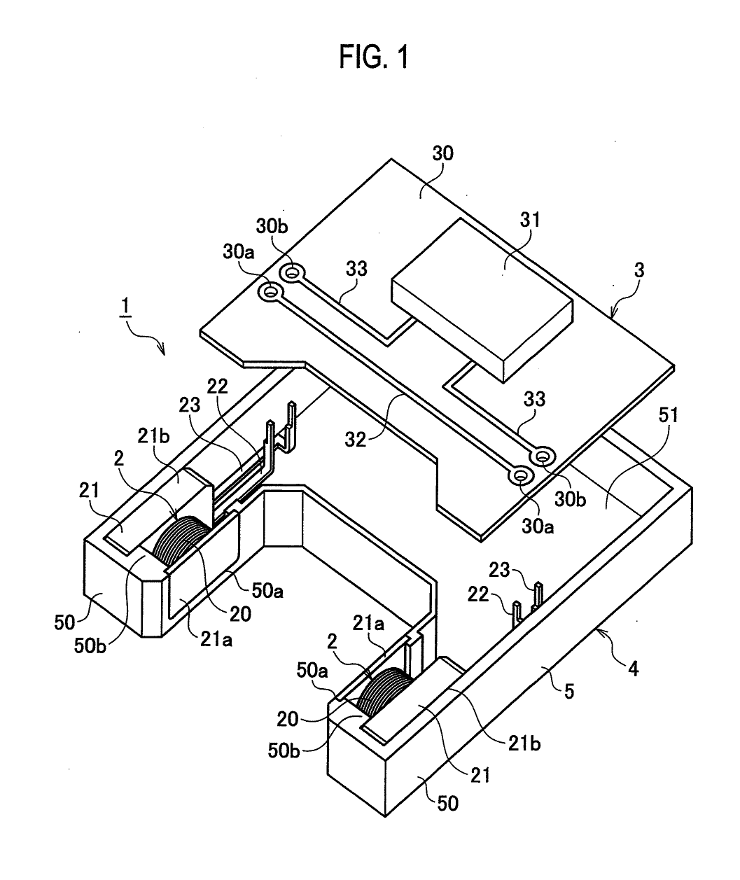

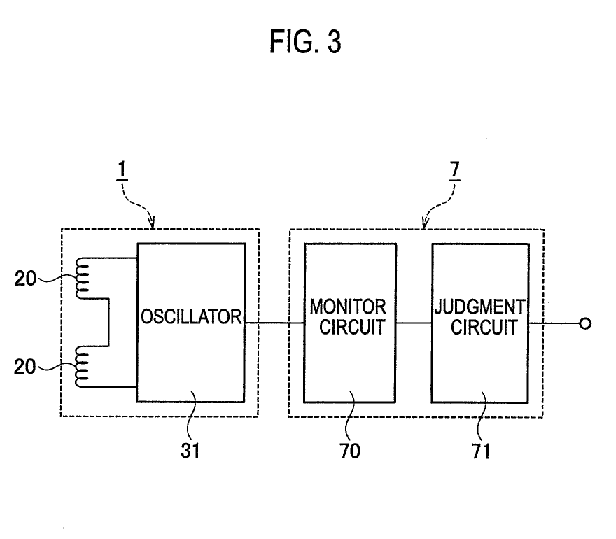

As illustrated in FIGS. 1 to 3, the proximity sensor includes a detector 1 for the proximity sensor including a sensing portion that has a central axis along a direction intersecting with (in the figure, perpendicular to) a moving direction of the sensed object 110 moving in a predetermined moving path in accordance with a movement of the movable body 100 and has a pair of sensing coils 20 configured to interpose the moving path, a circuit block 3 that includes a capacitor (not illustrated) composing an LC resonant circuit with the pair of the sensing coils 20 of the sensing portion and is provided with an oscillator 31 oscillating LC resonant circuit, and a housing 4 that houses those. The proximity sensor further includes a signal processor 7 that performs sensing for the sensed object 110 according to an oscillation condition of the LC resonant circuit of the detector 1 for the proximity sensor.

The sensing portion is composed of a pair of coil blocks 2. Each of the coil blocks 2 includes the sensing coil 20, a coil bobbin on which the sensing coil 20 is winded, a first connection terminal 22 used for connecting the respective sensing coils 20 between the pair of the coil blocks 2, and a second connection terminal 23 used for connecting the sensing coil 20 and the oscillator 31. The coil bobbin 21 is composed of a material such as a resin material having insulation property. The coil bobbin 21 integrally includes cylindrical winding barrel (not illustrated), and flanges 21a and 21b having a rectangular-plate shape provided at both ends in an axis direction of the winding barrel, respectively.

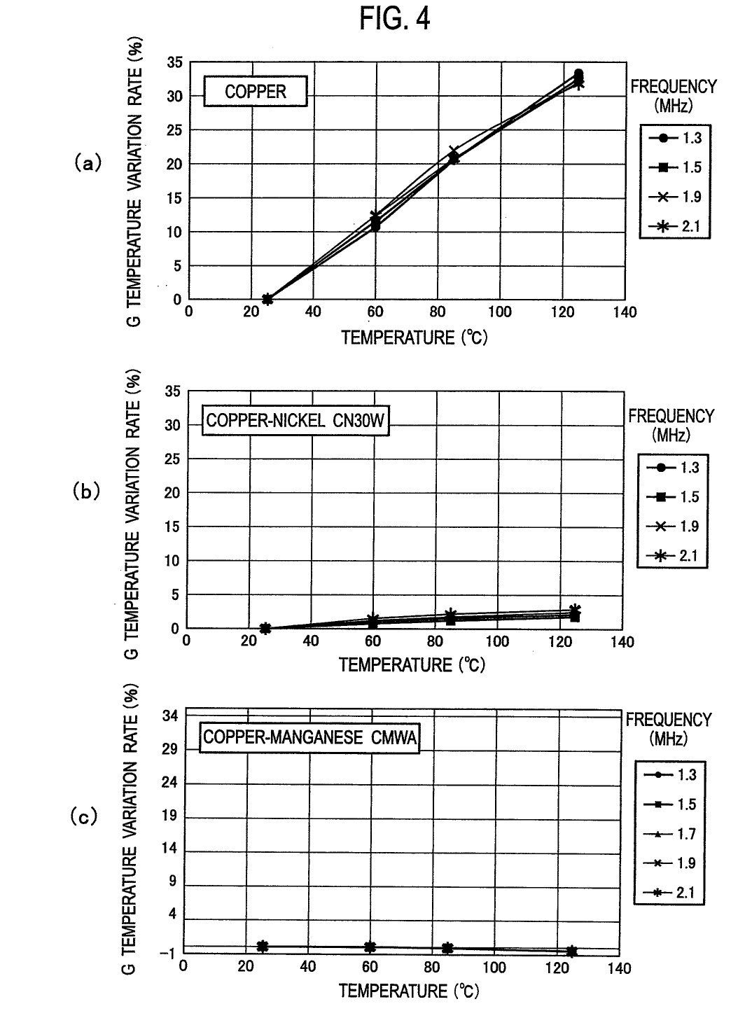

The sensing coil 20 is composed of conductor wire (winding), and wound on the winding barrel of the coil bobbin 21 at predetermined pitches and at a predetermined winding number. When the sensing coil 20 is composed of copper, a conductance of the sensing coil 20 largely varies according to an ambient temperature as illustrated in FIG. 4(a) due to a temperature coefficient of resistance and a volume resistivity of copper written in Table 1 as below. Note that, the G temperature change ratio in FIG. 4 represents a ratio of conductance change of the sensing coil 20 with respect to a conductance (G) of the sensing coil 20 at 25° C. Thus, when the sensing coil 20 is composed of copper, it is considered that sensor characteristics of the proximity sensor vary according to an ambient temperature. Therefore, in the present embodiment, the sensing coil 20 is composed of a copper-nickel alloy or a copper-manganese alloy. When the sensing coil 20 is composed of the copper-nickel alloy or the copper-manganese alloy, the conductance of the sensing coils 20 varies little according to an ambient temperature as illustrated in FIGS. 4(b) and 4(c) due to the temperature coefficient of resistance and the volume resistivity of copper written in Table 1 as below. Accordingly, temperature dependency of the sensor characteristics of the proximity sensor can be minimized due to the sensing coil 20 composed of the copper-nickel alloy or the copper-manganese alloy. Note that, a nickel-chrome alloy (temperature coefficient of resistance: 110, volume resistivity: 1.08) and a nickel-chrome-iron alloy (temperature coefficient of resistance: 150, volume resistivity: 1.12) can be used as the sensing coil 20 due to the similar temperature coefficient of resistance and volume resistivity.

TABLE 1

| | temperature coefficient | |
|---|---|---|
| | of resistance | volume resistivity |
| | ppm/K | μΩm |
| copper | 4000 | 0.017 |
| copper-nickel GCN30 | 180 | 0.30 |
| copper-manganese GCM44 | −10~+20 | 0.44 |

The connection terminals 22 and 23 are configured to have an elongated plate shape made of a conductive material (metallic material) and curved at predetermined portions. Each of the connection terminals 22 and 23 is inserted into the flange 21b of the coil bobbin 21. One end of the first connection terminal 22 is connected to one end of the sensing coil 20, and one end of the second connection terminal 23 is connected to the other end of the sensing coil 20. The other ends of the connection terminals 22 and 23 are laterally protruded from the flanges 21b, respectively.

The circuit block 3 is composed of a rectangular printed circuit board 30 and the oscillator 31 mounted on the printed circuit board 30. The oscillator 31 is composed of a plurality of electronic components including the capacitor composing the LC resonant circuit with the pair of the sensing coils 20. In the detector 1 for the proximity sensor in the present embodiment, the LC resonant circuit is constituted by connecting the capacitor in parallel to the pair of the sensing coils 20 connected in series. The oscillator 31 as described above includes, for example, a bias circuit (not illustrated) for supplying constant bias to the LC resonant circuit, and a current feedback circuit (not illustrated) for returning a current according to an oscillation voltage of the LC resonant circuit to the LC resonant circuit so as to maintain oscillation.

In the oscillator 31, as illustrated in FIG. 2(a), a negative conductance value is set so as to stop oscillation of the LC resonant circuit when the LC resonant circuit is oscillated while only the movable body 100 is positioned within a sensing range of the sensing coils 20, and when the movable body 100 moves and the sensed object 110 is positioned within the sensing range of the sensing coils 20. Namely, according to the detector 1 for the proximity sensor in the present embodiment, a presence or absence of the sensed object 110 can be sensed depending on the oscillation condition of the LC resonant circuit. The above-described oscillator 31 is conventionally well known, and the specific explanation thereof is omitted. Note that, in the FIGS. 1, 2 and 4 to 6, the oscillator 31 is simply illustrated.

The printed circuit board 30 is provided, at both ends in the longitudinal direction, with first through-holes 30a for a connection with the first connection terminals 22 and second through-holes 30b for a connection with the second connection terminals 23, each of which is penetrated in a thickness direction. On the surface of the printed circuit board 30 on which the oscillator 31 is mounted, a first conductor pattern 32 is formed to electrically connect the respective other ends of the first connection terminals 22 inserted through the through-holes 30a. In addition, second conductor patterns 33 are formed to electrically connect the other ends of the second connection terminals 23 inserted through the through-holes 30b to the oscillator 31. The circuit block 3 is further provided with, for example, an output terminal (not illustrated) for detecting oscillation amplitude of the LC resonant circuit composed of the sensing coils 20 and the oscillator 31.

As illustrated in FIG. 2(a), the housing 4 is composed of a box-shaped body 5 having one open side (left side in FIG. 2(a)), and a cover 6 attached to the body 5 to close the open side of the body 5. Both of the body 5 and cover 6 are made of a resin material having insulation property. Note that, the cover 6 is omitted in FIGS. 1 and 4 to 6. As illustrated in FIGS. 1 and 2, the body 5 is configured to have a U-shaped form interposing the moving path in the direction intersecting with (in the figures, perpendicular to) the moving direction of the sensed object 110 and including a pair of rectangular parallelepiped arms 50 for storing the coil blocks 2, and a rectangular parallelepiped main body 51 for integrally connecting both base end portions of the pair of the arms 50 and storing the circuit block 3. The arms 50 and the main body 51 are integrally connected so that each inside is communicated with each other. In the detector 1 for the proximity sensor in the present embodiment, as illustrated in FIGS. 2(a) and 2(b), the sensed object 110 is configured to move in a space between the pair of the arms 50. The cover 6 is configured to have a U-shaped plate shape having the same size as the body 5 so as to close the open side of the body 5.

Side surfaces on the moving path side in the pair of the arms 50 are provided with windows 50a engaging with the flanges 21a of the coil bobbins 21 and configured to face each other. Thus, in the detector 1 for the proximity sensor in the present embodiment, each flange 21a of the coil bobbins 21 composes a part of each side surface of the arms 50 of the body 5. In the inner surface at tip side in the arm 50, positioning rib 50b is protruded and integrally provided to engage with a gap between the flanges 21a and 21b of the coil bobbin 21. In addition, the main body 51 is, for example, provided with a hole (not illustrated) for bringing the output terminal of the circuit block 3 into the outside. At least the arms 50 are mounted on the device main body 200 so as to position in the flow path 210. Thus, the above-described housing 4 is waterproofed so that driving oil flowing in the flow path 210 does not flow into the housing 4.

The following is the description for a method of assembling the detector 1 for the proximity sensor in the present embodiment. Each of the coil blocks 2 is stored in the arm 50, in which the respective other ends of the connection terminals 22 and 23 are positioned in the main body 51. In this case, the coil block 2 is positioned to fix to the arm 50 by engaging the flange 21a of the coil bobbin 21 with the window 50a, and engaging the positioning rib 50b with the gap between the flanges 21a and 21b. In the coil block 2 stored in the arm 50 in a manner described above, the direction of the central axis of the sensing coil 20 is along the facing direction of the pair of the arms 50, i.e. the direction perpendicular to the moving path. The central axes of the sensing coils 20 of the pair of the coil blocks 2 stored in the pair of the arms 50 correspond with each other. Due to such a pair of the coil blocks 2, the sensing portion is configured to include the pair of the sensing coils 20 having the central axes along the direction intersecting with the moving direction of the sensed object 110 moving in the predetermined moving path, and provided so as to interpose the moving path.

The circuit block 3 is stored in the main body 51, in which the other ends of the first connection terminals 22 of the pair of the coil blocks 2 are inserted into the first through-holes 30a of the circuit block 3 so as to electrically connect the other ends of the first connection terminals 22 to the first conductor pattern 32 by soldering, or the like, and in which the other ends of the second connection terminals 23 of the pair of the coil blocks 2 are inserted into the second through-holes 30b of the circuit block 3 so as to electrically connect the other ends of the second connection terminals 23 to the second conductor patterns 33 by soldering, or the like. In such a way, the body 5 storing the coil blocks 2 and the circuit block 3 is provided with the cover 6 so as to close the open side of the body 5, thereby obtaining the detector 1 for the proximity sensor in the present embodiment.

In the detector 1 for the proximity sensor in the present embodiment, one ends of the pair of the sensing coils 20 are electrically connected with each other by the first connection terminals 22 and the first conductor pattern 32, and the other ends of the pair of the sensing coils 20 are electrically connected to the oscillator 31 by the second connection terminals 23 and the second conductor patterns 33. That means the connection terminals 22 and 23 and the conductor patterns 32 and 33 connect the sensing coils 20 of the sensing portion in series, and an electric connector for connecting the sensing coils 20 to the oscillator 31 is constituted.

The signal processor 7 includes a monitor circuit 70 for detecting the oscillation amplitude of the LC resonant circuit composed of the sensing coils 20 and the capacitor of the oscillator 31, and a judgment circuit 71 for sensing a presence or absence of the sensed object 110 based on the oscillation amplitude detected by the monitor circuit 70. The monitor circuit 70 is composed of a wave detector for detecting the oscillation amplitude of the LC resonant circuit by monitoring both terminal voltages of the LC resonant circuit (both terminal voltages of the capacitor of the oscillator 31 composing the LC resonant circuit). As for the above-mentioned monitor circuit 70, as a value to indicate oscillation amplitude, a circuit for detecting a peak value of the oscillation voltage, a circuit for detecting an integral value of the oscillation voltage, a circuit for detecting an effective value of the oscillation voltage, and the like can be employed. Conventionally well-known circuits can be employed as the monitor circuit 70, and the specific explanation thereof is omitted.

The judgment circuit 71 is composed of a comparator, for example. The judgment circuit 71 judges the oscillation condition of the LC resonant circuit based on the oscillation amplitude detected by the monitor circuit 70. When the oscillation is not in a stopped state, the judgment circuit 71 outputs a presence-sensing signal to indicate that the sensed object is not present within the sensing range of the sensing coils 20. While, when the oscillation is in a stopped state, the judgment circuit 71 generates the presence-sensing signal to indicate that the sensed object is present within the sensing range of the sensing coils 20 so as to output the signal.

According to the detector 1 for the proximity sensor as described above, the electric connector connects the respective sensing coils, and connects the sensing coils and the oscillator. Therefore, an expensive material (such as a heat-resistant insulating film metal wire rod) can be used for only the members to influence a sensing sensitivity (i.e. the sensing coils). Also, an inexpensive material (such as a common metallic terminal material) can be used for the electric connector. Thus, costs can be reduced while improving the sensing sensitivity. In addition, the electric connector is composed of the connection terminals 22 and 23, and the conductor patterns 32 and 33 formed on the printed circuit board 30. Then, at least a part of the electric connector is composed of the conductor pattern formed on the printed circuit board 30 of the circuit block 3. Therefore, the number of the components can be reduced, and the performance of the electric connector is stabilized due to little shape error. Furthermore, the sensing coil 20 is composed of any of a nickel-chrome alloy, a nickel-chrome-iron alloy, a copper-nickel alloy, and a copper-manganese alloy. Accordingly, the conductance of the sensing coil 20 does not largely vary by an ambient temperature, thereby lessening temperature dependency of the sensing portion characteristics.

In the detector 1 for the proximity sensor according to the present embodiment, the pair of the sensing coils 20 is configured to have the central axes along the direction intersecting with the moving direction of the sensed object 110 moving in the predetermined moving path. Thus, when the detector 1 for the proximity sensor is mounted, it is not necessary to pass the sensed object 110 through the sensing coils 20. Accordingly, it is not necessary to have a process to preliminarily pass the movable body 100 through the detector 1 for the proximity sensor when the movable body 100 is provided at a predetermined position with respect to a device (such as a hydraulic controller). Also, the steps of assembling the device are flexible, thereby easily proceeding with mounting operations. Moreover, it is possible to mount the detector 1 for the proximity sensor on the finished device later.

Furthermore, the pair of the sensing coils 20 is provided so as to interpose the moving path. When the sensed object 110 approaches one of the sensing coils 20, the sensed object 110 thus recedes from the other of the sensing coil 20 with a distance corresponding to the approach distance. The conductance of the pair of the sensing coils 20 varies little as a whole (i.e. each conductance of the pair of the sensing coils 20 complementarily varies). Therefore, it is possible to reduce influence of variations of a relative position of the sensed object 110 in the above-mentioned perpendicular direction with respect to the pair of the sensing coils 20, and achieve an improvement of sensing accuracy. Thus, the proximity sensor including the above-mentioned detector 1 for the proximity sensor can achieve the similar effect.

The inner surface of the sensing coil 20 may be provided with a rod-like core made of a magnetic material (such as a ferritic core) (an outer shape of the core may have, but not limited to, a round-bar shape and a square-bar shape). According to this configuration, when the winding number of the sensing coil 20 is the same, a flux can be enhanced more than the sensing coil 20 as an air core coil. Therefore, the conductance variation of the sensing coils 20 can be increased, thereby achieving the improvement of sensing accuracy.

While the sensing portion according to the present embodiment includes a set of the pair of the sensing coils 20, the sensing portion may include several sets of the pair of the sensing coils 20. In the present embodiment, while the pair of the sensing coils 20 is connected in series, the pair of the sensing coils 20 may be connected in parallel. In other words, the electric connector is to be a connector that may connect the sensing coils 20 of the sensing portion in series or in parallel (i.e. connect the sensing coils 20 with each other), and may connect the sensing coils 20 to the oscillator 31.

In the proximity sensor according to the present embodiment, the LC resonant circuit normally oscillates, and stops oscillation when the sensed object 110 is present within the sensing range of the sensing coils 20. Meanwhile, the LC resonant circuit may normally stop oscillation, and start oscillation when the sensed object 110 is present within the sensing range of the sensing coils 20. The sensed object 110 has a protruded disk-like shape provided at the periphery of the movable body 100. While, the movable body 100 may be configured to have a part thereof having a smaller outside diameter than an outside diameter of the movable body 100 itself by recessed in the periphery of the movable body 100, for example. Namely if a portion has a cross-section different from the movable body 100 in the surface perpendicular to the moving direction of the movable body 100, then such a portion can be varied the conductance of the sensing coils 20 and can be used as the sensed object 110.

### Second Embodiment

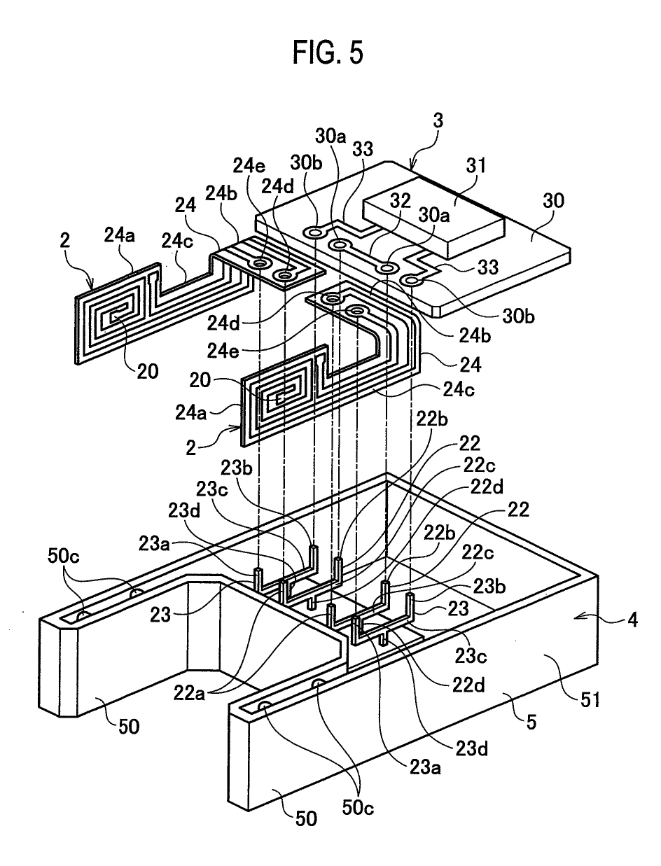

A proximity sensor according to the present embodiment has a different configuration of a detector 1 for the proximity sensor, especially in coil blocks 2 and a housing 4, from the first embodiment, as illustrated in FIG. 5. The other configuration is the same as the first embodiment, and the explanation thereof is omitted.

Each of the coil blocks 2 according to the present embodiment includes a support substrate 24 composed of a flexible substrate having flexibility, for example. A sensing coil 20 according to the present embodiment is composed of conductor pattern formed on the support substrate 24. Each of the coil blocks 2 according to the present embodiment does not include the connection terminals 22 and 23 according to the first embodiment. Connection terminals 22 and 23 according to the present embodiment are inserted into the main body 51 of the body 5. The first connection terminal 22 according to the present embodiment is made of a conductive material (metallic material), and integrally includes a terminal for coil 22a used for connecting with the coil block 2, a terminal for circuit 22b used for connecting with the circuit block 3, a junction 22c for connecting both base end portions of the terminal for coil 22a and the terminal for circuit 22b, and a support 22d protruding toward a direction opposite to the side of the both terminals 22a and 22b from the junction 22c.

The second connection terminal 23 according to the present embodiment, similar to the first connection terminal 22, integrally includes a terminal for coil 23a, a terminal for circuit 23b, a junction 23c, and a support 23d. In the first connection terminal 22, as the terminal for coil 22a and the terminal for circuit 22b protrude into the main body 51, a part of the support 22d is inserted into a base wall of the main body 51. In the second connection terminal 23, as the terminal for coil 23a and the terminal for circuit 23b protrude into the main body 51, a part of the support 23d is inserted into a base wall of the main body 51.

The support substrate 24 integrally includes a coil-forming portion 24a in which the sensing coil 20 is formed, a connector 24b provided with a first through-hole 24d for the terminal for coil 22a of the first connection terminal 22 and a second through-hole 24e for the terminal for circuit 23a of the second connection terminal 23, and a junction 24c for integrally connecting the coil-forming portion 24a and the connector 24b. One end of the sensing coil 20 is configured to extend so as to be connectable to the terminal for coil 22a of the first connection terminal 22 inserted through the first through-hole 23d. The other end of the sensing coil 20 is configured to extend so as to be connectable to the terminal for circuit 23a of the second connection terminal 23 inserted through the first through-hole 24e.

The housing 4 according to the present embodiment includes a body 5 mainly having a constitution different from the first embodiment. The body 5 according to the present embodiment includes ribs 50c that protrude and are integrally provided on respective surfaces opposite to inner surfaces on the moving path side in the arms 50 (i.e. opposite inner surfaces to inner surfaces on the moving path side in the arms 50) so as to hold the coil-forming portions 24a of the support substrates 24 between the ribs 50c and the inner surface at the moving path side, instead of providing the window 50a and the positioning rib 50b at the arm 50 according to the first embodiment.

The following is the description for a method of assembling the detector 1 for the proximity sensor according to the present embodiment. Each of the coil blocks 2 is stored in the body 5, so that the coil-forming portion 24a is located in the arm 50 and the connector 24b is located in the main body 51, respectively. In this case, the coil-forming portion 24a is held between the inner surfaces of the arm 50 and the ribs 50c. With regard to the coil block 2 stored in the arm 50, the direction of the central axis of the sensing coil 20 is along the facing direction of the pair of the arms 50, i.e. the direction perpendicular to the moving path. Also, the central axes of the sensing coils 20 of the pair of the coil blocks 2 stored in the pair of the arms 50 correspond with each other. Due to such a pair of the coil blocks 2, the sensing portion is configured to include the pair of the sensing coils 20 having the central axes along the direction intersecting with the moving direction of the sensed object 110 moving in the predetermined moving path, and provided so as to interpose the moving path.

The terminal for coil 22a of the first connection terminal 22 is inserted into the first through-hole 24d of the connector 24b of the support substrate 24 so as to electrically connect the terminal for coil 22a to one end of the sensing coil 20 by soldering, or the like. Similarly, the terminal for circuit 23a of the second connection terminal 23 is inserted into the second through-hole 24e of the connector 24b so as to electrically connect the terminal for circuit 23a to the other end of the sensing coil 20 by soldering, or the like.

The circuit block 3 is stored in the main body 51, in which the terminals for circuit 22b of the first connection terminals 22 are inserted into the first through-holes 30a, respectively, and in which the terminals for circuit 23b of the second connection terminals 23 are inserted into the second through-holes 30b, respectively. The terminals for circuit 22b of the first connection terminals 22 and the first conductor pattern 32 are electrically connected by soldering, or the like. Similarly, the terminals for circuit 23b of the second connection terminals 23 and the second conductor patterns 33 are electrically connected by soldering, or the like. The body 5 storing the coil blocks 2 and the circuit block 3 as described above is provided with the cover 6 so as to close the open side of the body 5, thereby obtaining the detector 1 for the proximity sensor according to the present embodiment.

In the detector 1 for the proximity sensor according to the present embodiment, the respective one ends of the pair of the sensing coils 20 are electrically connected with each other by the first connection terminals 22 and the first conductor pattern 32. Also, the respective other ends of the pair of the sensing coils 20 are electrically connected to the oscillator 31 by the second connection terminals 23 and the second conductor patterns 33. Thus, the detector 1 for the proximity sensor according to the present embodiment is configured to have the sensing coils 20 of the sensing portion connected in series by the connection terminals 22 and 23 and the conductor patterns 32 and 33, and the electric connector for connecting the sensing coils 20 to the oscillator 31.

According to the detector 1 for the proximity sensor described above, the sensing coils 20 achieving the similar effect to the first embodiment and composed of the conductor patterns are configured to be connected in series so as to locate a plurality of one-turn coils on the same flat surfaces. Therefore, when comparing with the case where a plurality of one-turn coils are connected in series to be aligned along a predetermined direction such as the sensing coil 20 (the sensing coil 20 of the first embodiment) composed of conductor wire (winding), the respective distances between the plurality of the one-turn coils and the sensed object are approximately the same. Thus, an improvement of a sensing sensitivity can be achieved due to the characteristics of the conductance variation and the like that largely vary according to the movement (approach/separation) of the sensed object 110. In addition, since a shape error is less compared with the sensing coil 20 composed of conductor wire, the performance of the sensing coil 20 is stabilized. Moreover, the problem hard to wind conductor wire caused by an arrangement location of the sensing coil 20 does not occur. Accordingly, the proximity sensor including the detector 1 for the proximity sensor described above can achieve the similar effect as well.

### Third Embodiment

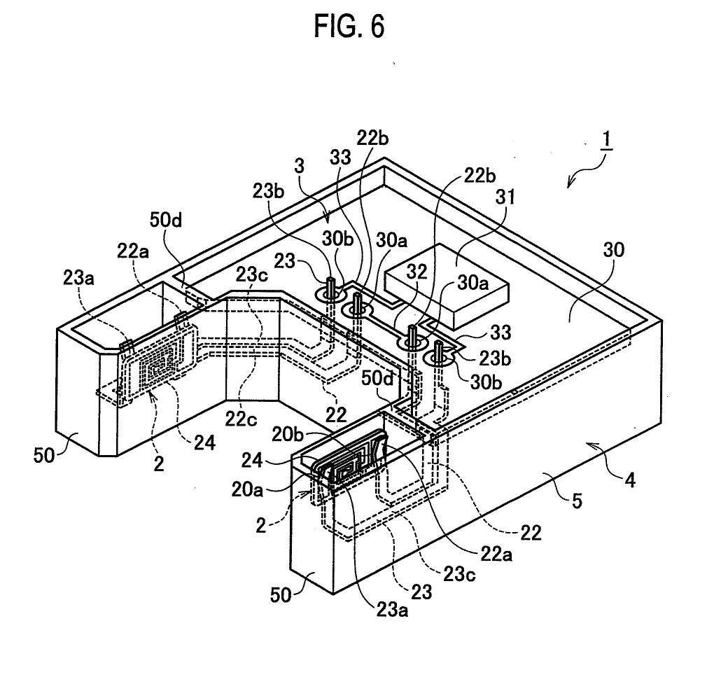

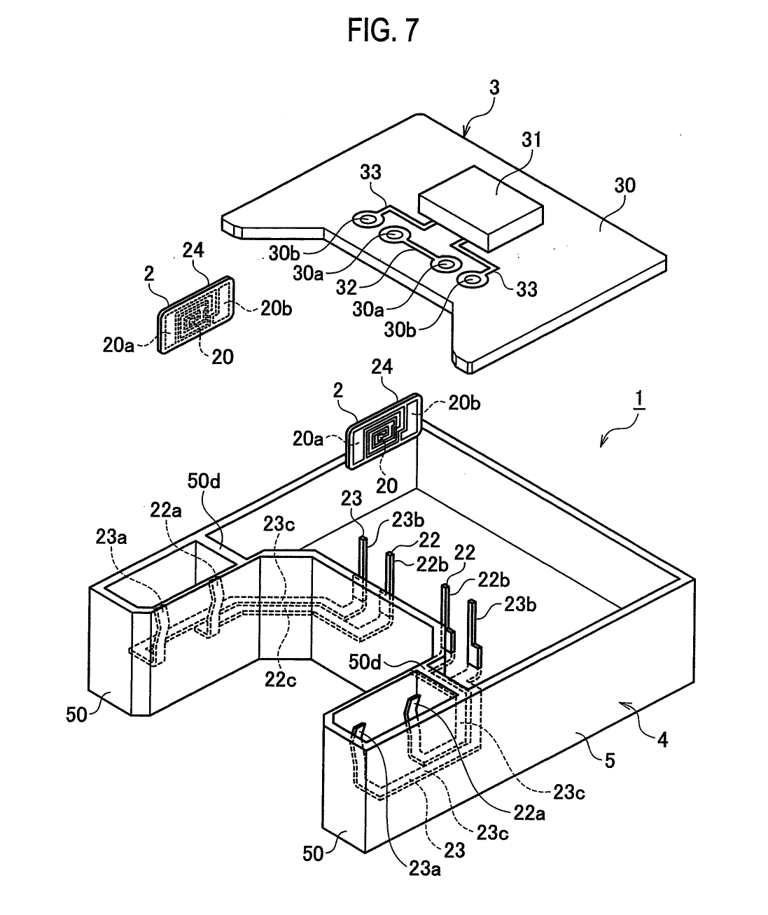

The proximity sensor according to the present embodiment has a different configuration of a detector 1 for the proximity sensor, especially in coil blocks 2 and a housing 4, from the second embodiment, as illustrated in FIGS. 6 and 7. The other configuration is the same as the second embodiment, and the explanation thereof is omitted.

Each of the coil blocks according to the present embodiment includes a rectangular-shaped support substrate 24 such as a glass epoxy substrate as illustrated in FIG. 6. The sensing coil 20 according to the present embodiment is composed of conductor patterns formed on the substrate 24 (in FIG. 6, some parts of the conductor patterns composing the sensing coil 20 are omitted for ease of illustration). One end of the sensing coil 20 is provided with a first pad 20a used for connecting with the first connection terminal 22, and the other end of the sensing coil 20 is provided with a second pad 20b used for connecting with the first connection terminal 23. The pads 20a and 20b of the sensing coil 20 are located at the both ends of the support substrate 24 in the longitudinal direction, respectively.

In the present embodiment, similar to the second embodiment, the connection terminals 22 and 23 are also inserted into the main body 1 of the body 5. The first connection terminal 22 according to the present embodiment is made of a conductive material (metallic material), and integrally includes a terminal for coil 22a used for connecting with the coil block 2, a terminal for circuit 22b used for connecting with the circuit block 3, and a junction 22c for connecting the both base end portions of the terminal for coil 22a and the terminal for circuit 22b. The second connection terminal 23 according to the present embodiment, similar to the first connection terminal 22 according to the present embodiment, integrally includes a terminal for coil 23a, a terminal for circuit 23b, and a junction 23c. The terminals for coil 22a and 23a elastically contact to the pad 20a so as to compose contacts contiguously connected to the sensing coil 20.

The first connection terminal 22 includes the junction 22c inserted in the base wall of the main body 51 so that the terminal for coil 22a protrudes in the arm 50 and the terminal for circuit 22b protrudes in the main body 51. Similarly, the second connection terminal 23 includes the junction 23c inserted in the base wall of the main body 51 so that the terminal for coil 23a protrudes in the arm 50 and the terminal for circuit 23b protrudes in the main body 51.

The housing 4 according to the present embodiment includes a body 5 mainly having a constitution different from the second embodiment. The body 5 according to the present embodiment includes separators 50d for separating the arms 50 from the main body 51, instead of including the ribs 50c according to the second embodiment. The separators 50d prevent the coil blocks 2 from shifting from the arms 50 to the main body 51.

The following is the description for a method of assembling the detector 1 for the proximity sensor according to the present embodiment. The coil block 2 is stored in the arm 50. In this case, the pad 20a of the sensing coil 2 is elastically provided with the terminal for coil 22a of the first connection terminal 22, and the pad 20b is elastically provided with the terminal for coil 23a of the second connection terminal 23. Thus, the sensing coil 20 is pushed to the inner surface on the moving path side in the arm 50, and held between the terminals for coil 22a and 23a and the inner surface of the arm 50. With regard to the coil block 2 stored in the arm 50, the direction of the central axis of the sensing coil 20 is along the facing direction of the pair of the arms 40, i.e. the direction perpendicular to the moving path. Also, the central axes of the sensing coils 20 of the pair of the coil blocks 2 stored in the pair of the arms 50 correspond with each other. Due to such a pair of the coil blocks 2, the sensing portion is configured to include the pair of the sensing coils 20 having the central axes along the direction intersecting with the moving direction of the sensed object 110 moving in the predetermined moving path, and provided so as to interpose the moving path.

The circuit block 3 is stored in the main body 51, in which the terminals for circuit 22b of the first connection terminals 22 are inserted into the first through-holes 30a, respectively, and in which the terminals 23b of the second connection terminals 23 are inserted into the second through-holes 30b, respectively. The terminals for circuit 22b of the first connection terminals 22 and the first conductor pattern 32 are electrically connected by soldering, or the like. Similarly, the terminals for circuit 23b of the second connection terminals 23 and the second conductor patterns 33 are electrically connected by soldering, or the like. The body 5 storing the coil blocks 2 and the circuit block 3 as described above is provided with the cover 6 so as to close the open side of the body, thereby obtaining the detector 1 for the proximity sensor according to the present embodiment.

In the detector 1 for the proximity sensor according to the present embodiment, the respective one ends of the pair of the sensing coils 20 are electrically connected with each other by the first connection terminals 22 and the first conductor pattern 32. Also, the respective other ends of the pair of the sensing coils 20 are electrically connected to the oscillator 31 by the first connection terminals 23 and the second conductor patterns 33. Thus, the detector 1 for the proximity sensor according to the present embodiment is configured to have the sensing coils 20 of the sensing portion connected in series by the connection terminals 22 and 23 and the conductor patterns 32 and 33, and the electric connector for connecting the sensing coils 20 to the oscillator 31.

According to the detector 1 for the proximity sensor described above, the similar effect to the second embodiment can be achieved. In addition, the connection terminals 22 and 23 composing the electric connector include the terminals for coil 22a and 23a as contacts contiguously connected to the sensing coils 20. Moreover, each of the sensing coils 20 is held between the terminals for coil 22a and 23a and the inner surface of the arm 50. Therefore, it is possible to easily attach the sensing coils 20 and improve assembling efficiency. Accordingly, the proximity sensor according to the present embodiment including the detector 1 for the proximity sensor described above can achieve the similar effect as well.

### Fourth Embodiment

The proximity sensor according to the present embodiment has a configuration including a plurality of sensing portions, which is different from the proximity sensor of the first embodiment including only one sensing portion. A detector 1 for the proximity sensor according to the present embodiment is provided with a plurality of sensing portions aligned along the moving direction of the sensed object 110, as described in Japanese Patent Application No. 2007-109749. According to this configuration, the detector 1 for the proximity sensor according to the present embodiment includes a plurality of the oscillators 31 provided corresponding to the respective sensing portions, whereby the LC resonant circuits with the corresponding number to the plurality of the sensing portions is constituted. Note that, the other configuration is the same as the first embodiment, and the figure and explanation thereof are omitted.

The detector 1 for the proximity sensor according to the present embodiment can thus achieve the similar effect to the first embodiment, and includes the plurality of the sensing portions provided adjacent the moving area of the sensed object 110 and configured to align in the moving direction of the sensed object 110. Therefore, position sensing for the sensed object 110 can be performed depending on which conductance of the sensing coils 20 of the sensing portions varies. Thus, it is possible to use the proximity sensor as a position sensor by using the detector 1 for the proximity sensor in the present embodiment.

For example, when the proximity sensor is constituted by using the above-mentioned detector 1 for the proximity sensor, a signal processor 7 for determining whether the sensed object is present within the respective sensing ranges of the sensing coils 20 of the plurality of the sensing portions according to the respective oscillation conditions of the plurality of the LC resonant circuits in the detector 1 for the proximity sensor, and for performing position sensing for the sensed object 110 based on combinations of the determination results may be used, instead of using the signal processor 7 according to the first embodiment.

The signal processor 7 according to the present embodiment is composed of a plurality of the monitor circuits 70 corresponding to the respective oscillators 31 in the detector 1 for the proximity sensor, a plurality of the judgment circuits 71 corresponding to the respective monitor circuits 70, and an overall determination unit (not illustrated) for performing position sensing for the sensed object 110 based on the combinations of the determination results of the judgment circuits 71. The monitor circuits 70 and the judgment circuit 71 are as described above, and the explanation thereof is omitted.

The overall determination unit generates and outputs a position sensing signal expressing the position of the sensed object 110 depending on which sensing portion of the plurality of the sensing portions senses the presence of the sensed object 110. For example, when the detector 1 for the proximity sensor includes the two sensing portions, the judgment circuit 71 corresponding one sensor outputs a present sensing signal expressing the presence of the sensed object 110 when the sensed object 110 is present only within the sensing range of the sensing coils 20 of one sensing portion. While, the judgment circuit 71 corresponding to the other sensing portion outputs a present sensing signal expressing the absence of the sensed object 110. Thus, the overall determination unit determines that the sensed object 110 is present only within the sensing range of the sensing coils 20 of one sensing portion, thereby outputting the position sensing signal expressing the position of the sensed object 110. Accordingly, the proximity sensor in the present embodiment can achieve low cost while improving the sensing sensitivity, and perform position sensing for the sensed object 110. Note that, the configuration of the detector 1 for the proximity sensor in the present embodiment (the configuration including the plurality of the sensing portions) can be applied to the second and third embodiments as well.

The embodiments adopting the invention made by the inventors are described hereinbefore. However, the present invention is not limited to the description and figures composing one part of the disclosure of the present invention according to the embodiments. For example, the present invention can also be applied to an analog output type proximity sensor and a detector thereof as disclosed in Japanese Patent No. 4026405. Thus, all the other embodiments, examples, operational technologies and the like made by one of ordinary skill in the art and the like are included in the category of the present invention based on the present embodiments.

### INDUSTRIAL APPLICABILITY

The present invention can be applied to the non-contact proximity sensor for sensing the sensed object made of metals (conductive materials), magnetic materials, and the like.

1. A detector for a proximity sensor, comprising:
one or more sensing portions, each of the sensing portions including at least one pair of sensing coils, the pair of sensing coils having central axes along a direction intersecting with a moving direction of a sensed object moving in a predetermined moving path and provided so as to interpose the moving path;
a circuit block including a capacitor composing an LC resonant circuit with the sensing coils of the sensing portion and provided with an oscillator for oscillating the LC resonant circuit; and
an electric connector composed of conductive materials, connecting the sensing coils of the sensing portions in series or in parallel, and connecting the sensing coils to the oscillator.

2. The detector for a proximity sensor of claim 1, wherein
a plurality of the sensing portions are provided so as to align along the moving direction of the sensed object.

3. The detector for a proximity sensor of claim 1, wherein
each of the sensing coils is composed of a conductor pattern formed on a support substrate.

4. The detector for a proximity sensor of claim 1, further comprising:
a plurality of arms provided so as to interpose the moving path in the direction intersecting with the moving direction of the sensed object, each of the arms storing the sensing coil; and
a housing connecting base ends of the plurality of the arms and including a main body storing the circuit block, wherein
the electric connector includes contacts contiguously connected to the sensing coils and holds the sensing coils between the contacts and inner surfaces of the arms.

5. The detector for a proximity sensor of claim 1, wherein
the circuit block is composed of a printed circuit board and electronic components mounted on the printed circuit board to compose the oscillator, and at least a part of the electric connector is composed of a conductor pattern formed on the printed circuit board.

6. The detector for a proximity sensor of claim 1, wherein
each of the sensing coils is composed of a nickel-chrome alloy, a nickel-chrome-iron alloy, a copper-nickel alloy, or a copper-manganese alloy.

7. A proximity sensor, comprising:
the detector for a proximity sensor of claim 1; and
a signal processor for performing sensing for the sensed object according to an oscillation condition of the LC resonant circuit of the sensing portion.

8. A proximity sensor, comprising:
the detector for a proximity sensor according to claim 2; and
a signal processor for determining whether the sensed object is present within respective sensing ranges of the sensing coils of a plurality of the sensing portions according to respective oscillation conditions of a plurality of the LC resonant circuits of the sensing portions, and performing position sensing for the sensed object based on combinations of determination results.
